(19) United States
(12) Patent Application Publication
(10) Pub. No.: US 2022/0342635 A1
(43) Pub. Date: Oct. 27, 2022

(54) One-Transistor Processing Element For Non-Volatile Memory Crossbar Array

(71) Applicant: THE REGENTS OF THE UNIVERSITY OF MICHIGAN, Ann Arbor, MI (US)

(72) Inventors: Michael FLYNN, Ann Arbor, MI (US); Seungheun SONG, Ann Arbor, MI (US); Justin CORRELL, Ann Arbor, MI (US)

(73) Assignee: THE REGENTS OF THE UNIVERSITY OF MICHIGAN, Ann Arbor, MI (US)

(21) Appl. No.: 17/727,124

(22) Filed: Apr. 22, 2022

Related U.S. Application Data
(60) Provisional application No. 63/178,814, filed on Apr. 23, 2021.

(51) Int. Cl. G06F 7/523; G11C 11/54

(52) U.S. Cl. CPC G06F 7/523; G11C 11/54

(57) ABSTRACT

Crossbar arrays perform analog vector-matrix multiplication naturally and provide a building block for modern computing systems. In many applications, the weights stored in the crossbar array are learned off-line and then stored on embedded devices. After the weights are learned, they do not change. Since the weights do not change in these applications, this disclosure envisions a new implementation for the processing elements of the crossbar array.

### CROSS-REFERENCE TO RELATED APPLICATIONS

This application claims the benefit of U.S. Provisional Application No. 63/178,814 filed on Apr. 23, 2021. The entire disclosure of the above application is incorporated herein by reference.

### FIELD

The present disclosure relates to implementing processing elements of non-volatile memory crossbar arrays solely with a single transistor.

### BACKGROUND

Machine learning or artificial intelligence (AI) tasks use neural networks to learn and then to infer. The workhorse of many types of neural networks is vector-matrix multiplication—computation between an input and weight matrix. Learning refers to the process of tuning the weight values by training the network on vast amounts of data. Inference refers to the process of presenting the network with new data for classification.

Crossbar arrays perform analog vector-matrix multiplication naturally. Each row and column of the crossbar is connected through a processing element (PE) that represents a weight in a weight matrix. Inputs are applied to the rows as voltage pulses and the resulting column currents are scaled, or multiplied, by the PEs according to physics. The total current in a column is the summation of each PE current.

In many applications, weights are learned off-line and then stored on embedded devices. Moreover, after the weights are learned, they do not change. Since the weights do not change in these applications, this disclosure envisions a new implementation for the processing elements of the crossbar array.

This section provides background information related to the present disclosure which is not necessarily prior art.

### SUMMARY

This section provides a general summary of the disclosure, and is not a comprehensive disclosure of its full scope or all of its features.

A computing system is presented. The computing system is comprised of an array of memory cells arranged in columns and rows, such that memory cells in each row of the array are interconnected by a respective drive line and each column of the array is interconnected by a respective bit line. Each memory cell is implemented solely by a transistor, where the on resistance of the transistor represents the weight of a given memory cell, wherein each memory cell is configured to receive an input signal indicative of a multiplier and operates to output a product of the multiplier and the weight of the given memory cell onto the corresponding bit line of the given memory cell, where the value of the multiplier is encoded in the input signal. The computing system further includes a plurality of drive line circuits interfaced with the array of memory cells, where each drive line circuit is electrically connected to a respective drive line in the array of memory cells; and a plurality of bit line circuits interfaced with the array of memory cells, each bit line circuit is electrically connected to a respective bit line in the array of memory cells.

The computing system may also include a plurality of word line circuits interfaced with the array of memory cells, where each word line circuit is electrically connected to gate terminals of transistors comprising a column in the array of memory cells and operates the transistors in the triode region.

In one aspect, the on resistance of a transistor varies across transistors in the array of memory cells. In this way, different weights are assigned to the memory cells in the array of memory cells. More specifically, a WI ratio varies across transistors in the array of memory cells, such that the WI ratio is width of gate terminal of a given transistor in an array of memory cells to length of gate terminal of the given transistor in the array of memory cells.

In another aspect, a digital-to-analog converter is interconnected between each of the drive line circuits and its respective drive line.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a diagram of an example implementation for a computing system.

FIG. 2 is a diagram depicting an example embodiment for the computing system in accordance with this disclosure.

FIG. 3 is a partial schematic showing a memory cell implemented by a MOSFET.

FIGS. 4A-4C are schematics of memory cells illustrating how to implement a two bit arrangement.

FIG. 5 is a diagram illustrating a technique for improving the crossbar array against nonlinearity of the transistor.

FIG. 6 is a diagram illustrating a technique for controlling voltage applied to the control terminal of the MOSFETs.

Corresponding reference numerals indicate corresponding parts throughout the several views of the drawings.

### DETAILED DESCRIPTION

Example embodiments will now be described more fully with reference to the accompanying drawings.

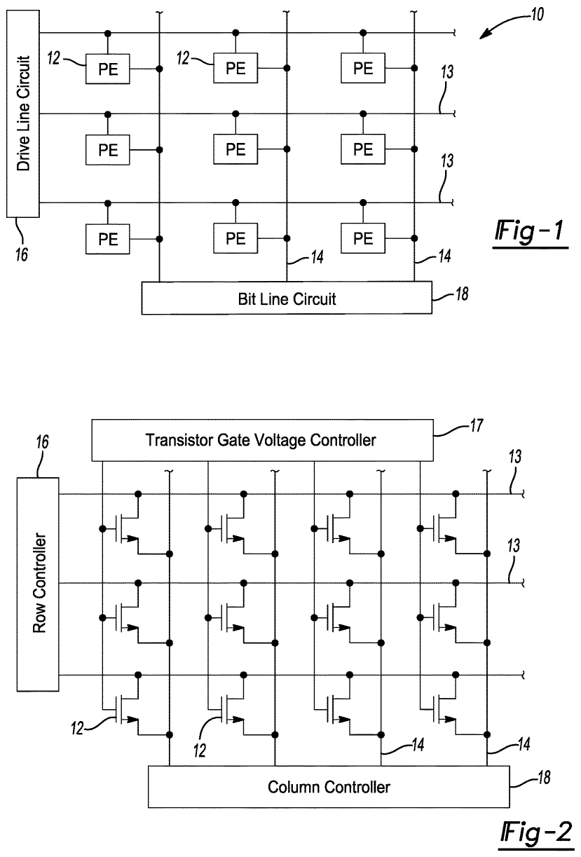

FIG. 1 depicts an example implementation for a computing system 10. The core of the computing system is an array of memory cells 12 (also referred to as processing elements) arranged in columns and rows and commonly referred to as a crossbar array. The memory cells 12 in each row of the array are interconnected by a respective drive line 13; whereas, the memory cells 12 in each column of the array are interconnected by a respective bit line 14. In some embodiments, the memory cells in each column of the array are also interconnected by respective word lines. Memory cells 12 can take many different forms including but not limited to resistive random-access memory, flash memory and other non-volatile memory technologies.

In the example embodiment, the computing system employs an analog approach where an analog value is stored in each memory cell. During operation, each memory cell 12 is configured to receive an input signal indicative of a multiplier and operates to output a product of the multiplier and the value stored in the given memory cell onto the corresponding bit line of a given memory cell. The value of the multiplier is encoded in the input signal.

Dedicated mixed-signal peripheral hardware is interfaced with the rows and columns of the crossbar arrays. The peripheral hardware supports read operations in relation to the memory cells comprising the crossbar array. With reference to FIG. 2, the peripheral hardware includes a drive line switch matrix (or circuits) 16, a wordline switch matrix (or circuits) 17 and a bitline switch matrix (or circuits) 18.

FIG. 2 further depicts an example embodiment for the computing system 10. In the example embodiment, each memory cell 12 is implemented solely by a transistor, where on resistance of the transistor represents the weight of a given memory cell. That is, the value of the stored weight is determined by transistor geometry. For example, the value of the weight may be determined by the WI ratio, where w is the width of gate terminal of a transistor and I is length of gate terminal of the transistor. Because weights do not change once they are learned in many applications, this approach simplifies the circuit arrangement. It is readily understood that the on resistance of the transistor can vary across the different transistors in the array of memory cells, thereby assigning different weights to the memory cells in the array of memory cells.

In other embodiments, the memory cell 12 may be implemented by two or more transistors. For example, the memory cell 12 can be implemented by two transistors coupled in parallel in adjacent columns. Other arrangements of two or more transistors coupled together are also contemplated by this disclosure.

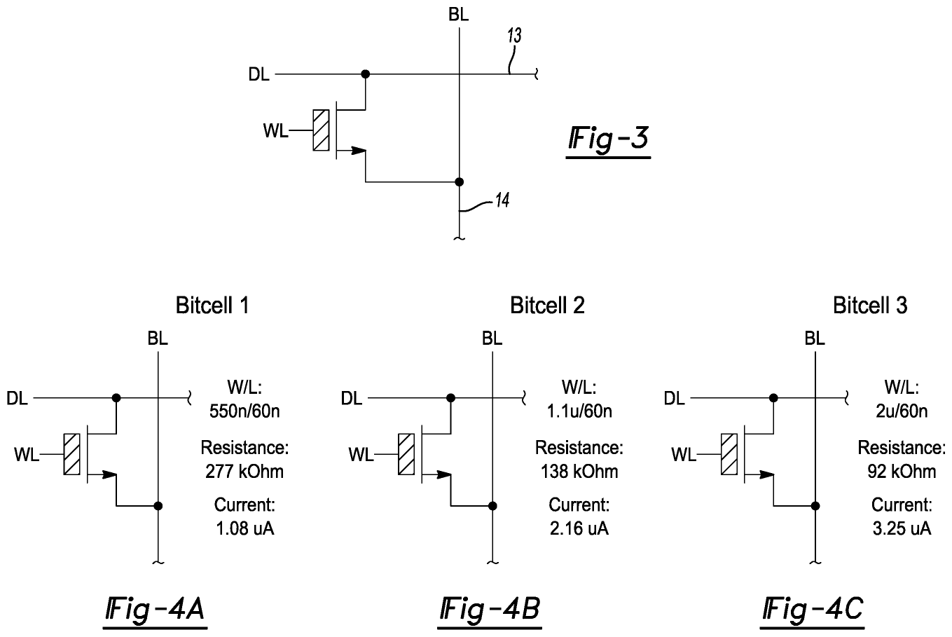

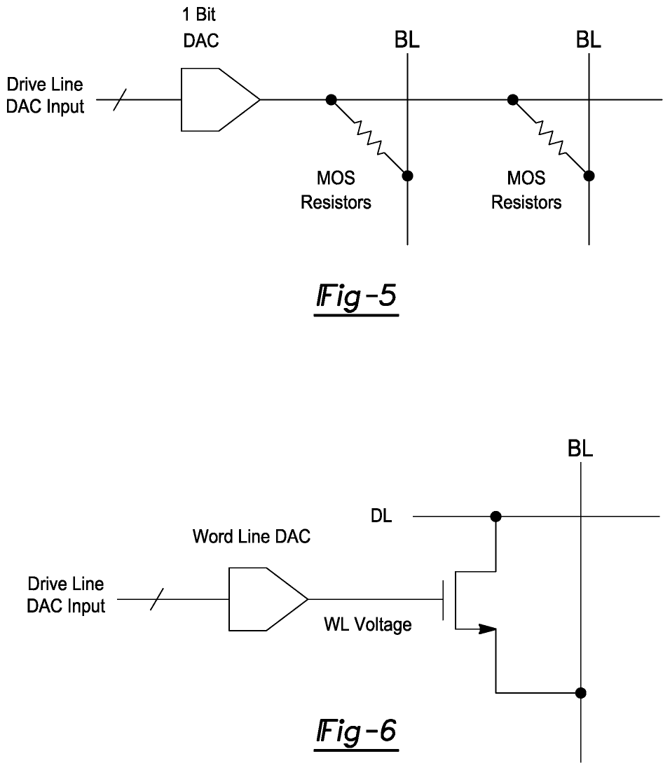

In the example embodiment, the transistors in the array of memory cells are further defined as metal-oxide-semiconductor field effect transistors (MOSFET) as seen in FIG. 3. For MOSFETs, the drain terminal is electrically connected to the respective drive line; whereas, the source terminal is electrically connected to the respective bit line. In addition, the gate terminal of the MOSFET is electrically connected to the respective word line, where a bias voltage applied to the gate terminal operates the MOSFET in the triode region. While reference is made herein to MOSFETs, it is readily understood that other type of transistors also fall within the broader aspects of this disclosure.

FIGS. 4A-4C further illustrate an example of a MOSFET with a two bit arrangement. To achieve a two-bit arrangement, the MOSFET needs to exhibit four different conductance values. For one conductance value, the MOSFET has w/I ratio of 550 nm/60 nm which results in on resistance of 277 kOhm. For a second conductance value, the MOSFET has w/I ration of 1.1 μm/60 nm which results in on resistance of 138 kOhm. For a third conductance value, the MOSFET has w/I ratio of 2 μm/60 nm which results in 92 kOhm. For a fourth conductance value, the MOSFET is not connected which results in an infinite effective resistance (i.e., zero conductance). This zero-conductance state is beneficial as compared to other memory technologies. This is merely one example of how MOSTFETs can be configured to yield different conductance values and thus represent different weights.

In some embodiments, value of the input signal on each driveline is encoded with a binary code. To improve the crossbar array against nonlinearity of the transistor resistance, a one bit digital-to-analog converter is placed on each drive line as shown in FIG. 5. This approach implies a bitwise or a pulse-width modulation operation for the crossbar array.

In the wordline switch matrix 17, one or more digital-to-analog converters may be used to generate the wordline voltages. In one embodiment, a single DAC, in cooperation with a series of switches, may be used to selectively deliver the wordline voltages to select wordlines. In this case, the DAC is shared between the wordlines.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A computing system, comprising:
an array of memory cells arranged in columns and rows, such that memory cells in each row of the array are interconnected by a respective drive line and each column of the array is interconnected by a respective bit line;
each memory cell is implemented solely by a transistor, where on resistance of the transistor represents weight of a given memory cell, wherein each memory cell is configured to receive an input signal indicative of a multiplier and operates to output a product of the multiplier and the weight of the given memory cell onto the corresponding bit line of the given memory cell, where the value of the multiplier is encoded in the input signal;
a plurality of drive line circuits interfaced with the array of memory cells, each drive line circuit is electrically connected to a respective drive line in the array of memory cells; and
a plurality of bit line circuits interfaced with the array of memory cells, each bit line circuit is electrically connected to a respective bit line in the array of memory cells.

2. The computing system of claim 1 wherein on resistance of a transistor varies across transistors in the array of memory cells, thereby assigning different weights to the memory cells in the array of memory cells.

3. The computing system of claim 2 wherein WI ratio varies across transistors in the array of memory cells, such that the WI ratio is width of gate terminal of a given transistor in an array of memory cells to length of gate terminal of the given transistor in the array of memory cells.

4. The computing system of claim 1 wherein the transistors in the array of memory cells is further defined as metal-oxide-semiconductor field effect transistor.

5. The computing system of claim 1 further comprises a plurality of word line circuits interfaced with the array of memory cells, each word line circuit is electrically connected to gate terminals of transistors comprising a column in the array of memory cells and operates the transistors in the triode region.

6. The computing system of claim 1 further comprise a digital-to-analog converter interconnected between each of drive line circuits and its respective drive line.

7. A computing system, comprising:
an array of memory cells arranged in columns and rows, such that memory cells in each row of the array are interconnected by a respective drive line and each column of the array is interconnected by a respective bit line;
each memory cell consisting only of a metal-oxide-semiconductor field effect transistor, where on resistance of the transistor represents weight of a given memory cell, wherein each memory cell is configured to receive an input signal indicative of a multiplier and operates to output a product of the multiplier and the weight of the given memory cell onto the corresponding bit line of the given memory cell, where the value of the multiplier is encoded in the input signal;
a plurality of drive line circuits interfaced with the array of memory cells, each drive line circuit is electrically connected to a respective drive line in the array of memory cells; and
a plurality of bit line circuits interfaced with the array of memory cells, each bit line circuit is electrically connected to a respective bit line in the array of memory cells.

8. The computing system of claim 7 wherein on resistance of a transistor varies across transistors in the array of memory cells, thereby assigning different weights to the memory cells in the array of memory cells.

9. The computing system of claim 8 wherein WI ratio varies across transistors in the array of memory cells, such that the WI ratio is width of gate terminal of a given transistor in an array of memory cells to length of gate terminal of the given transistor in the array of memory cells.

10. The computing system of claim 7 further comprises a plurality of word line circuits interfaced with the array of memory cells, each word line circuit is electrically connected to gate terminals of transistors comprising a column in the array of memory cells and operates the transistors in the triode region.

11. The computing system of claim 7 further comprise a digital-to-analog converter interconnected between each of drive line circuits and its respective drive line.
